(19) United States
(12) Patent Application Publication
(10) Pub. No.: US 2026/0164570 A1
(43) Pub. Date: Jun. 11, 2026

(54) ELECTRONIC DEVICE

(71) Applicant: TOYOTA JIDOSHA KABUSHIKI KAISHA, Toyota-shi (JP)

(72) Inventor: Takashi ASANO, Okazaki-shi (JP)

(73) Assignee: TOYOTA JIDOSHA KABUSHIKI KAISHA, Toyota-shi (JP)

(21) Appl. No.: 19/403,396

(22) Filed: Nov. 28, 2025

(30) Foreign Application Priority Data
Dec. 11, 2024 (JP) 2024-216275

(51) Int. Cl. H05K 5/00

(52) U.S. Cl. CPC H05K 5/0069

(57) ABSTRACT

In the electronic device for accommodating an electronic component in a case, the case has an outer peripheral wall surrounding a space in which the electronic component is disposed, a plug-in port for fixing by inserting a connector electrically connected to the electronic component is provided on the outer peripheral wall, and the space is partitioned into a first region in which the electronic component is disposed and a second region in which the plug-in port is opened, the partition wall portion is provided inside the case, and the partition wall portion has a gripping wall portion that faces parallel to the plug-in port.

### CROSS-REFERENCE TO RELATED APPLICATION

This application claims priority to Japanese Patent Application No. 2024-216275 filed on Dec. 11, 2024. The disclosure of the above-identified application, including the specification, drawings, and claims, is incorporated by reference herein in its entirety.

### BACKGROUND

### 1. Technical Field

The present disclosure relates to an electronic device in which an electronic component is housed in a case, and more particularly, to an electronic device in which a plug-in port for interposition and removal of a connector is provided in a part of an outer wall.

### 2. Description of Related Art

The assembly process of the electronic device of this type necessarily includes a step of connecting the connector, and the connection work is required to be performed efficiently in the same manner as the assembly of a substrate into the case. Japanese Unexamined Patent Application Publication No. 2018-046124 (JP 2018-046124 A) describes a structure in which, when inserting a harness connector into an interposition opening provided in a housing of a terminal block, a harness-side connection terminal can be easily inserted to the position of a housing-side connection terminal. In the structure described in JP 2018-046124 A, when the harness connector is inserted into the interposition opening from the obliquely upper side, the harness-side connection terminal is guided toward the housing-side connection terminal disposed horizontally. As a portion for performing the guide, there are provided a tip-side inclined portion having a small inclination angle on the interposition opening side, and a rear-side inclined portion that is continuous with the tip-side inclined portion and has a larger inclination angle toward the housing-side connection terminal.

Another example of an electronic device having a connection terminal is described in Japanese Unexamined Patent Application Publication No. 2012-249483 (JP 2012-249483 A). The power conversion device described in JP 2012-249483 A has a configuration in which a plurality of substrates is housed in a housing. A terminal for connection of a connector is provided so as to protrude to the outside of the housing, and the terminal and the substrates are connected to each other by a printed wiring board inside the housing.

### SUMMARY

When assembling the devices described in JP 2018-046124 A and JP 2012-249483 A, the connector is inserted into the interposition opening or connected to the terminal protruding to the outside of the housing. In this case, in order to suppress the connector easily coming off, a certain large pushing force is applied to the connector so that the connector is firmly fitted to the interposition opening or the housing. Therefore, when the process of inserting the connector is performed by an automatic machine, it is necessary that the pushing force for the connector should be received at any location. However, the devices described in JP 2018-046124 A and JP 2012-249483 A do not consider automation of assembly. Therefore, JP 2018-046124 A and JP 2012-249483 A do not disclose at all the technical issue for performing the interposition of the connector using an automatic machine, a preferable configuration for inserting the connector into the interposition opening, or the like.

The present disclosure has been made in view of the above circumstances, and an object of the present disclosure is to provide an electronic device that enables an automatic machine to easily insert a connector into a plug-in port that is opened through an outer wall of a case.

In order to achieve the above object, an aspect of the present disclosure provides an electronic device in which an electronic component is housed in a case, in which:
the case includes an outer peripheral wall that surrounds a space in which the electronic component is disposed;
the outer peripheral wall is provided with a plug-in port that allows interposition and fixation of a connector to be electrically connected to the electronic component;
a partition wall portion that partitions the space into a first region in which the electronic component is disposed and a second region in which the plug-in port is opened is provided inside the case; and
the partition wall portion includes a gripping wall portion that faces the plug-in port in parallel with the plug-in port.

In an aspect of the present disclosure,
the plug-in port may be provided in a direction inclined at a predetermined angle with respect to the outer peripheral wall located in front in a direction of interposition of the connector; and
the gripping wall portion may be parallel to the plug-in port in the direction inclined at the predetermined angle.

In an aspect of the present disclosure, an upper end surface of the gripping wall portion may be a guide surface inclined downward toward an opposite side of a side of the plug-in port.

In an aspect of the present disclosure, the gripping wall portion may have a structure in which the gripping wall portion has a higher bending rigidity than a portion of the partition wall portion other than the gripping wall portion.

In an aspect of the present disclosure,
the partition wall portion may extend from an inner surface of the outer peripheral wall to a predetermined location inside the space;
the electronic device may further include a relay terminal block that extends from the first region to the second region while bypassing an end portion of the partition wall portion extending to the predetermined location inside the space; and
the electronic component may be connected to one end of the relay terminal block, and the connector may be connected to the other end of the relay terminal block.

In the present disclosure, a gripping wall portion is provided inside the case so as to face the plug-in port for the connector. When the connector is pushed into the plug-in port, an appropriate pressing tool is brought into contact with a surface of the gripping wall portion opposite to the surface facing the plug-in port, whereby a reaction force can be generated by the pressing tool or the gripping wall portion. Therefore, no load that moves the case is generated, and thus it is not necessary to hold the case against some fixed portion, or to provide such a fixed portion, and it is possible to easily perform the work of inserting the connector using an automatic machine. In addition, the gripping wall portion separates a region in which the plug-in port is opened and a region in which the electronic component is disposed. Therefore, even if foreign matter (contamination) enters the case from the plug-in port before the connector is inserted into the plug-in port or in the course of inserting the connector, the foreign matter can be kept in the region on the plug-in port side. As a result, it is possible to suppress intrusion of the foreign matter to the electronic component side. In this manner, the partition wall portion functions as a pressing portion when inserting the connector, and performs the function of suppressing intrusion of foreign matter to the electronic component side. Thus, so-called commonization of one component or portion can be achieved to simplify the configuration as a whole.

In particular, when the plug-in port is inclined, that is, when there is no portion parallel to the plug-in port at any location of the outer wall of the case, a reaction force cannot be generated by the outer wall when the connector is inserted into the plug-in port. However, in the present disclosure, the gripping wall portion is provided in parallel with the so-called inclined plug-in port. Therefore, by attaching an appropriate holding tool to the gripping wall portion, it is possible to cancel the load for inserting the connector and the reaction force against the load in the case. As a result, no force that acts to change the position or direction of the case is generated, and thus it is not necessary to provide a jig, a receiving portion, or the like for holding the case, and it is possible to facilitate the work of inserting the connector using an automatic machine.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a perspective view showing an embodiment of the present disclosure with a lid plate or a top plate removed;

FIG. 2 is a schematic longitudinal sectional view of the gripping wall portion and the plug-in port;

FIG. 3 is a schematic plan view of a case where a relay terminal block is provided.

### DETAILED DESCRIPTION OF EMBODIMENTS

Embodiments of the present disclosure will now be described with reference to the accompanying drawings. Note that the embodiments described below are merely examples of the implementation of the present disclosure, and are not intended to limit the present disclosure.

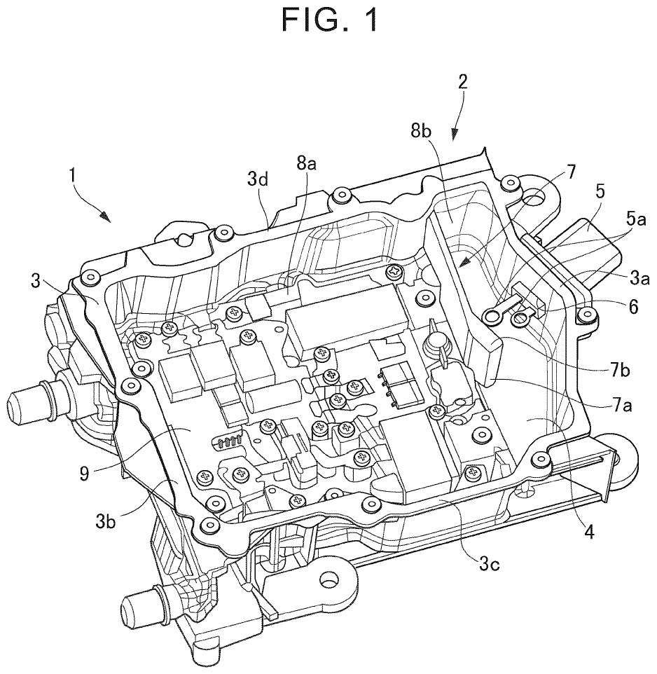

FIG. 1 shows an embodiment of the present disclosure, in which the electronic device 1 is, for example, a DC/DC converter. The electronic device 1 is configured by accommodating electronic components inside the case 2, and FIG. 1 shows a state in which the inside can be seen by removing the lid plate or the top plate of the case 2. The case 2 has an outer peripheral wall 3 and a bottom plate portion 4 which surround the whole, and the outer peripheral wall 3 has a substantially rectangular parallelepiped shape as a whole. That is, a pair of wall portions long in the circumferential direction and a wall portion short in the circumferential direction connecting the wall portions encircles the whole, one of the wall portions has a shape bent toward the inside and outside of the case 2. In the example shown in FIG. 1, one of the pair of wall portions short in the circumferential direction has a shape bent toward the inside and the outside of the case 2. Hereinafter, it is assumed that the bent wall portion is the front wall portion 3a, the other wall portion which is short in the circumferential direction is the rear wall portion 3b, one of the pair of wall portions which is long in the circumferential direction is the left wall portion 3c, and the other is the right wall portion 3d.

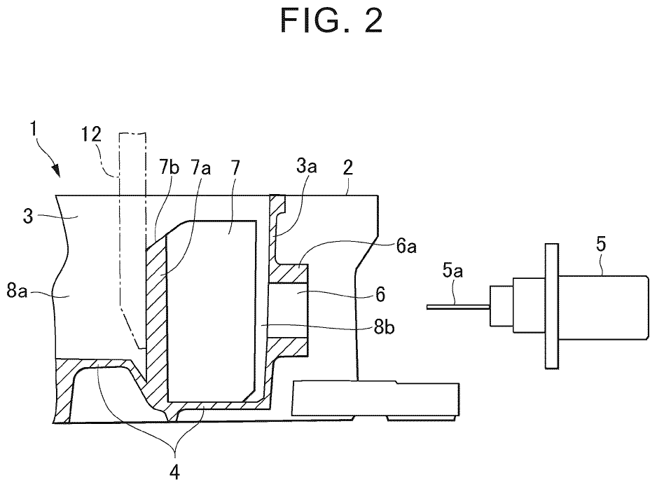

The front wall portion 3a is provided with a plug-in port 6 for inserting and fixing the connector 5. FIG. 2 is a cross-sectional view for explaining the configuration of the plug-in port 6, and the plug-in port 6 is formed in a substantially central portion in the vertical direction of the front wall portion 3a so as to penetrate the front wall portion 3a in the thickness direction thereof, in other words, in a direction parallel to the bottom plate portion 4 or in a horizontal direction. A boss portion 6a protruding perpendicularly to the front wall portion 3a is formed at an open end of the plug-in port 6 on an outer surface of the front wall portion. The connector 5 is electrically connected to the electronic device 1 by inserting a cylindrical part at its distal end into the plug-in port 6 so as to be fitted without looseness inside the boss portion 6a. In the connector 5, the terminal 5a protrudes to the distal end, and when the connector is inserted into the plug-in port 6, the terminal 5a extend to the inside of the case 2. Therefore, the case 2 not only opens to the upper surface side, but also opens to the outside at the plug-in port 6 in a state before the connector 5 is inserted.

A part of the front wall portion 3a in which the plug-in port 6 is provided is inclined with respect to the outer peripheral wall 3 positioned in the plug-in direction of the connector 5, more specifically, one of the side wall portions 3c, 3d described above. Here, “inclined” means that the intersection angle between the center axial line of the plug-in port 6 along the direction of interposition of the connector 5 and the outer peripheral wall 3 (the rear wall portion 3b or one of the side wall portions 3c, 3d) is not a right angle. In other words, the plug-in port 6 is oriented obliquely with respect to the longitudinal direction of the rectangular parallelepiped formed by the outer peripheral wall 3, and the part in which the plug-in port 6 is provided is not parallel to or opposed to the rear wall portion 3b.

A partition wall portion 7 is provided to partition the internal space of the case 2 partitioned by the outer peripheral wall 3 and the bottom plate portion 4. The partition wall portion 7 is provided at a position close to the front wall portion 3a where the plug-in port 6 is formed, at a position where the terminal 5a of the connector 5 inserted into the plug-in port 6 does not touch. The partition wall portion 7 is a plate-shaped portion that rises from the bottom plate portion 4 and extends from one side wall portion (right side wall portion in FIG. 1) 3d to the inside of the case 2, and is formed integrally with the bottom plate portion 4 and the outer peripheral wall 3. The height of the partition wall portion 7 is equal to or higher than the height of the plug-in port 6 from the bottom plate portion 4. Therefore, the inside of the case 2 is partitioned by the partition wall portion 7 into a first region 8a on the rear wall portion 3b side and a second region 8b in which the plug-in port 6 is opened.

More specifically, the partition wall portion 7 extends linearly from the inner surface of the one side wall portion (for example, the right side wall portion) 3d toward the other side wall portion (for example, the left side wall portion) 3c. The distal end position thereof exceeds the position at which the plug-in port 6 is opened to 3c of the other side wall portion (for example, the left side wall portion). In the partition wall portion 7, a portion corresponding to a position where the plug-in port 6 extends in the direction of interposition is bent so as to face the plug-in port 6 in parallel with the plug-in port 6. A part that is parallel to the plug-in port 6 is a gripping wall portion 7a in the present embodiment. As will be described later, the gripping wall portion 7a is a portion for generating a reaction force against a pushing force when the connector 5 is inserted into the plug-in port 6. Therefore, the upper surface of the gripping wall portion 7a is a guide surface 7b inclined downward toward the side surface opposite to the plug-in port 6. Also, the gripping wall portion 7a may be thicker than the other portions of the partition wall portion 7, or a rib (not shown) may be formed on the front or back surface thereof, in order to increase strength or flexural stiffness over the other portions. Further, the partition wall portion 7 may extend from the gripping wall portion 7a further toward the other side wall portion 3c, but does not reach the other side wall portion 3c.

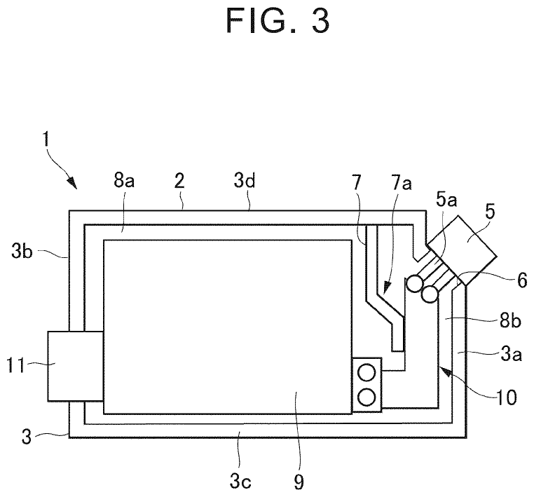

A circuit board 9 as an electronic component is disposed inside the first region 8a partitioned by the partition wall portion 7, and is fixed to the bottom plate portion 4. The relay terminal block 10 for conducting the terminal 5a of the connector 5 to the circuit board 9 can be provided inside the case 2. FIG. 3 is a schematic plan view illustrating an example in which the relay terminal block 10 is provided inside the case 2. The relay terminal block 10 has a strip-shaped conductor such as a bus bar or a printed wire, and the conductor extends from the first region 8a to the second region 8b by bypassing the distal end portion of the partition wall portion 7 described above. One end thereof is connected to the circuit board 9, and the other end thereof is connected to the terminal 5a of the connector 5. In FIG. 3, reference numeral “11” denotes an output-side connector.

In the electronic device 1 described above, the circuit board 9 is mounted inside the case 2, and then the connector 5 is inserted into the plug-in port 6. Further, the terminal 5a is connected to the relay terminal block 10. When the connector 5 is inserted into the plug-in port 6, there is a possibility that foreign matter adhering to the connector 5, the plug-in port 6, or the like may enter the inside of the case 2. However, the first region 8a in which the electronic components such as the circuit board 9 are disposed is separated from the second region 8b in which the plug-in port 6 is opened by the partition wall portion 7. Therefore, the foreign matter entering the second region 8b is suppressed from reaching the electronic components such as the circuit board 9, and the trouble caused by the foreign matter is suppressed.

Further, since the direction of the plug-in port 6 is inclined with respect to the longitudinal direction of the case 2 as described above, the pushing force for inserting the connector 5 acts on the case 2 in the direction of rotating the case 2. However, in the above-described electronic device 1, the gripping wall portion 7a is provided so as to be parallel to the plug-in port 6 and face each other. Therefore, the rear surface of the gripping wall portion 7a facing away from the plug-in port 6, for example, the appropriate pressing tool 12 as schematically shown in FIG. 2, if the connector 5 is inserted into the plug-in port 6 in that condition, it will be received by the gripping wall portion 7a the force for pushing the connector 5. As a result, the case 2 is not moved, and the connector can be easily inserted into the plug-in port 6.

In particular, when an automated machine (not shown) such as a robotic machine for assembly is used, a tongue-shaped member that collectively sandwiches the connector 5 and the gripping wall portion 7a can be used. In addition, even when an automatic machine such as a robot for assembly is used, a load that moves or rotates the entire case 2 or the electronic device 1 is not generated. For this reason, it is not necessary to dispose a member or a portion for fixing the case 2 around the case 2 or to form the member or the portion on the outer peripheral portion of the case 2. In this respect, it is also possible to simplify the interposition process of the connector 5 or the assembly process of the electronic device 1.

Further, when the pressing tool 12 or a tongue-shaped member (not shown) is applied to the gripping wall portion 7a, the members are lowered from the upper side of the gripping wall portion 7a. However, since the upper surface of the gripping wall portion 7a has a guide surface 7b inclined as described above, even if there is a slight positional deviation, it is possible to easily fit the rear surface of the gripping wall portion 7a by sliding the members on the guide surface 7b.

It should be noted that the present disclosure is not limited to the above-described embodiment, and in essence, the gripping wall portion may be provided as a part of the partition wall portion, and the shape of the partition wall portion as a whole may not be the above-described shape. In addition, the case does not have to have a rectangular parallelepiped shape, and may have an appropriate shape such as a rectangular shape, a polygonal shape, or a deformed polygonal shape in a case where the case is cut horizontally.

What is claimed is:

1. An electronic device in which an electronic component is housed in a case, wherein:
the case includes an outer peripheral wall that surrounds a space in which the electronic component is disposed;
the outer peripheral wall is provided with a plug-in port that allows interposition and fixation of a connector to be electrically connected to the electronic component;
a partition wall portion that partitions the space into a first region in which the electronic component is disposed and a second region in which the plug-in port is opened is provided inside the case; and
the partition wall portion includes a gripping wall portion that faces the plug-in port in parallel with the plug-in port.

2. The electronic device according to claim 1, wherein:
the plug-in port is provided in a direction inclined at a predetermined angle with respect to the outer peripheral wall located in front in a direction of interposition of the connector; and
the gripping wall portion is parallel to the plug-in port in the direction inclined at the predetermined angle.

3. The electronic device according to claim 1, wherein an upper end surface of the gripping wall portion is a guide surface inclined downward toward an opposite side of a side of the plug-in port.

4. The electronic device according to claim 1, wherein the gripping wall portion has a structure in which the gripping wall portion has a higher bending rigidity than a portion of the partition wall portion other than the gripping wall portion.

5. The electronic device according to claim 1, wherein:
the partition wall portion extends from an inner surface of the outer peripheral wall to a predetermined location inside the space;
the electronic device further includes a relay terminal block that extends from the first region to the second region while bypassing an end portion of the partition wall portion extending to the predetermined location inside the space; and
the electronic component is connected to one end of the relay terminal block, and the connector is connected to the other end of the relay terminal block.
